(19) United States
(12) Patent Application Publication
(10) Pub. No.: US 2026/0282756 A1
(43) Pub. Date: Sep. 17, 2026

(54) ELECTRIC AND MAGNETO-IONIC SWITCHING OF MAGNETIC TUNNEL JUNCTIONS

(71) Applicant: GEORGETOWN UNIVERSITY, Washington, DC (US)

(72) Inventors: Christopher JENSEN, Arlington, VA (US); Dhritiman BHATTACHARYA, Washington, DC (US); Kai LIU, Falls Church, VA (US)

(21) Appl. No.: 19/566,911

(22) Filed: Mar. 13, 2026

Related U.S. Application Data
(60) Provisional application No. 63/772,067, filed on Mar. 14, 2025.

(51) Int. Cl. H10N 50/10; G06N 3/065; G11C 11/16; H10N 50/01; H10N 50/85

(52) U.S. Cl. CPC H10N 50/10; G06N 3/065; G11C 11/161; H10N 50/01; H10N 50/85

(57) ABSTRACT

A magnetic tunnel junction (MTJ) device that uses the magneto-ionic effect to control the tunnel magnetoresistance (TMR) between an anchored ferromagnetic (FM) layer and a free FM layer. The magneto-ionic MTJ includes an ion reservoir adjacent to one of the FM layers. By applying a voltage across the MTJ, ions from the ion reservoir can be driven to the adjacent FM layer, thereby reducing the TMR. Those ions may then be driven from the adjacent FM layer, thereby increasing the TMR, by reversing the bias of the applied voltage. The magneto-ionic MTJ enables scalable, low-power, electric-field-controlled switching (e.g., between binary states) without the high current density required to set conventional MTJ devices. Additionally, because the ion penetration and TMR is discretely or continuously controllable, the magneto-ionic MTJ may form an analog or non-Boolean device (e.g., neuromorphic computing element, multi-bit storage element, dynamically tunable magnetic sensor, physical unclonable function for hardware security).

### FEDERAL FUNDING

This invention was made with government support under ECCS2151809 awarded by the National Science Foundation. The government has certain rights in the invention.

### CROSS-REFERENCE TO RELATED APPLICATIONS

This application claims priority to U.S. Prov. Pat. Appl. No. 63/772,067, filed Mar. 14, 2025, which is hereby incorporated by reference.

### BACKGROUND

Magnetic tunnel junctions (MTJs) have become a cornerstone technology in modern electronics, serving as the fundamental building block for a wide range of spintronic devices.

FIGS. 1A and 1B are diagrams illustrating a prior art MTJ 100. In the example of FIGS. 1A and 1B, the MTJ 100 includes two ferromagnetic (FM) layers 140 and 160 separated by an insulating layer 150. The FM layers 140 and 160 include an “anchored” FM layer 140 (having a magnetization direction 148) and a “free” FM layer 160 (having a magnetization direction 168). The magnetization direction 148 of the anchored FM layer 140 is “anchored” (or “pinned”) by an antiferromagnetic (AF) anchor layer 120, which uses interfacial exchange coupling to stabilize the magnetization direction 148 of the anchored FM layer 140.

In the example of FIGS. 1A and 1B, the FM layers 140 and 160 exhibit perpendicular magnetic anisotropy (PMA), meaning the magnetization directions 148 and 168 are each perpendicular to the plane formed by the respective layer 140 or 160. (In other MTJs, the magnetization direction 148 and/or 168 may be “in-plane”; i.e., parallel to the plane formed by the respective layer 140 and/or 160.)

FIG. 1A illustrates the MTJ 100 in a parallel state 172, in which the magnetization direction 168 of the free FM layer 160 is substantially parallel to the magnetization direction 148 of the anchored FM layer 140. FIG. 1B illustrates the MTJ 100 in an antiparallel state 174, in which the magnetization direction 168 of the free FM layer 160 is substantially antiparallel to the magnetization direction 148 of the anchored FM layer 140 (i.e., the magnetization direction 168 of the free FM layer 160 is rotated approximately 180 degrees relative to the magnetization direction 148 of the anchored FM layer 140).

Because magnetic tunnel junctions exhibit tunnel magnetoresistance (TMR), the electrical resistance 190 across the MTJ 100 changes based on the magnetic alignment of the two ferromagnetic layers 140 and 160. In the example of FIGS. 1A and 1B, for instance, the resistance 190 in the parallel state 172 of FIG. 1A is lower than the resistance 190 in the antiparallel state 174 of FIG. 1B.

That tunnel magnetoresistance has enabled widespread adoption of magnetic tunnel junctions in non-volatile memory, such as Magnetic Random Access Memory (MRAM). Magnetic tunnel junctions also have other unique characteristics, such as low readout current and non-volatile data retention without steady-state power consumption, which make them highly advantageous for logic applications and magnetic sensors. Magnetic tunnel junctions have also been incorporated into hard disk drive read heads, true random number generators, and neuromorphic computing devices that mimic the synapses and neurons for artificial intelligence (AI) hardware.

Despite those advantages, the integration of magnetic tunnel junctions into high-density commercial devices faces significant scalability challenges. Conventional switching mechanisms typically require two orthogonal write lines to generate the magnetic fields necessary to switch the magnetic orientation of the free layer. By increasing the physical footprint of the device and generating stray magnetic fields that can interfere with adjacent elements, those write lines restrict how closely MTJs can be packed. While alternative switching methods—such as spin-transfer torque (STT) and spin-orbit torque (SOT)—have been introduced to reduce the reliance on external magnetic fields, those methods still require high current densities to switch a bit, thereby resulting in considerable energy dissipation. Additionally, switching of MTJs through electric field-controlled voltage control of magnetic anisotropy (VCMA) has been demonstrated. However, the maximum change in anisotropy that can be induced by VCMA is small. Furthermore, conventional VCMA is volatile in nature and requires additional external bias field for 180° magnetization reversal. These ultimately lead to scalability issues beyond a certain dimension.

Accordingly, there is a need for a mechanism that enables scalable, electric-field-controlled switching of magnetic tunnel junctions without the need for bulky write lines or high-current injection.

### SUMMARY

In order to overcome those and other drawbacks of the prior art, disclosed is a “magneto-ionic” magnetic tunnel junction (MTJ) device that uses the magneto-ionic effect to control the tunnel magnetoresistance (TMR) between an anchored ferromagnetic (FM) layer and a free FM layer. The magneto-ionic MTJ includes an ion reservoir adjacent to one of the FM layers. By applying a voltage across the MTJ, ions from the ion reservoir can be driven to the adjacent FM layer, thereby reducing the TMR. Those ions may then be driven from the adjacent FM layer, thereby increasing the TMR, by reversing the bias of the applied voltage.

The magneto-ionic MTJ enables scalable, low-power, electric-field-controlled switching (e.g., between binary states) without the high current density required to set conventional MTJ devices.

Additionally, because the ion penetration and TMR is discretely or continuously controllable, the magneto-ionic MTJ may form an analog or non-Boolean device, such as an artificial neuron of a neuromorphic computing device, a multi-bit storage element, a dynamically tunable magnetic sensor, a physical unclonable function for hardware security, etc.

### BRIEF DESCRIPTION OF THE DRAWINGS

Aspects of exemplary embodiments may be better understood with reference to the accompanying drawings. The components in the drawings are not necessarily to scale, emphasis instead being placed upon illustrating the principles of exemplary embodiments.

FIG. 1A is a diagram illustrating an example prior art magnetic tunnel junction (MTJ) in a parallel state.

FIG. 1B is a diagram illustrating the prior art MTJ of FIG. 1A in an antiparallel state.

FIG. 2 is a diagram illustrating a magneto-ionic MTJ according to exemplary embodiments.

FIG. 3A is a diagram illustrating application of a forward bias voltage across the magneto-ionic MTJ of FIG. 2 according to exemplary embodiments.

FIG. 3B is a diagram illustrating application of a reverse bias voltage across the magneto-ionic MTJ of FIG. 2 according to exemplary embodiments.

FIG. 4 is a block diagram illustrating a specific example of the prior art MTJ of FIG. 1.

FIG. 5 is a block diagram illustrating a specific exemplary embodiment of the magneto-ionic MTJ of FIG. 2.

FIG. 6 illustrates an example contact pad layout.

FIG. 7A is a graph illustrating the relative tunnel magnetoresistance (TMR), as a function of magnetic field, of the prior art MTJ of FIG. 4.

FIG. 7B is a graph illustrating the relative TMR, as a function of magnetic field, of the magneto-ionic MTJ of FIG. 5.

### DETAILED DESCRIPTION

Reference to the drawings illustrating various views of exemplary embodiments is now made. In the drawings and the description of the drawings herein, certain terminology is used for convenience only and is not to be taken as limiting the embodiments of the present invention. Furthermore, in the drawings and the description below, like numerals indicate like elements throughout.

As used herein, a first element being “adjacent to” a second element should be interpreted to include embodiments where the first element is directly adjacent to the second element and embodiments where one or more additional elements are position in between the first element and the second element. In the string “ABCD”, for example, “A” is adjacent to “C” opposite “D”.

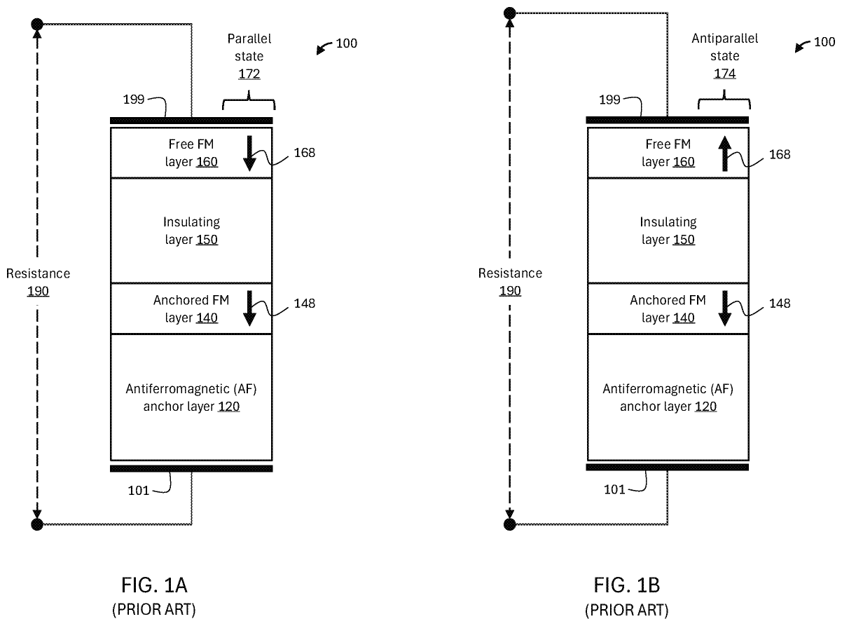

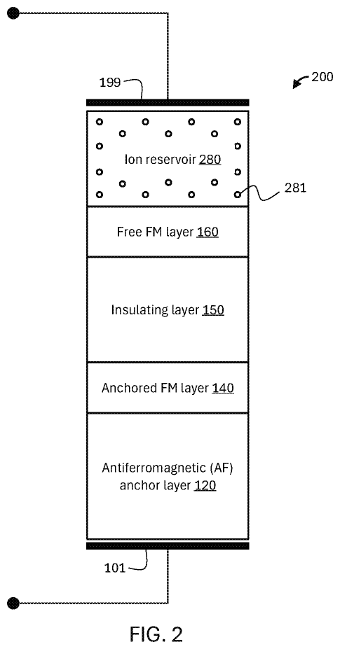

FIG. 2 is a block diagram of a magneto-ionic magnetic tunnel junction (MTJ) 200 according to exemplary embodiments. Like the prior art MTJ 100 of FIGS. 1A and 1B, the magneto-ionic MTJ 200 includes an anchored ferromagnetic (FM) layer 140, which is separated from a free FM layer 160 by an insulating layer 150 and anchored by an antiferromagnetic (AF) anchor layer 120. In some embodiments, the FM layers 140 and 160 may have magnetization directions 148 and 168 that are perpendicular to the plane of the respective FM layer 140 or 160 as described above with reference to FIGS. 1A and 1B. In other embodiments, the magnetization direction 148 and/or 168 may be “in-plane” (i.e., parallel to the plane formed by the respective layer 140 and/or 160).

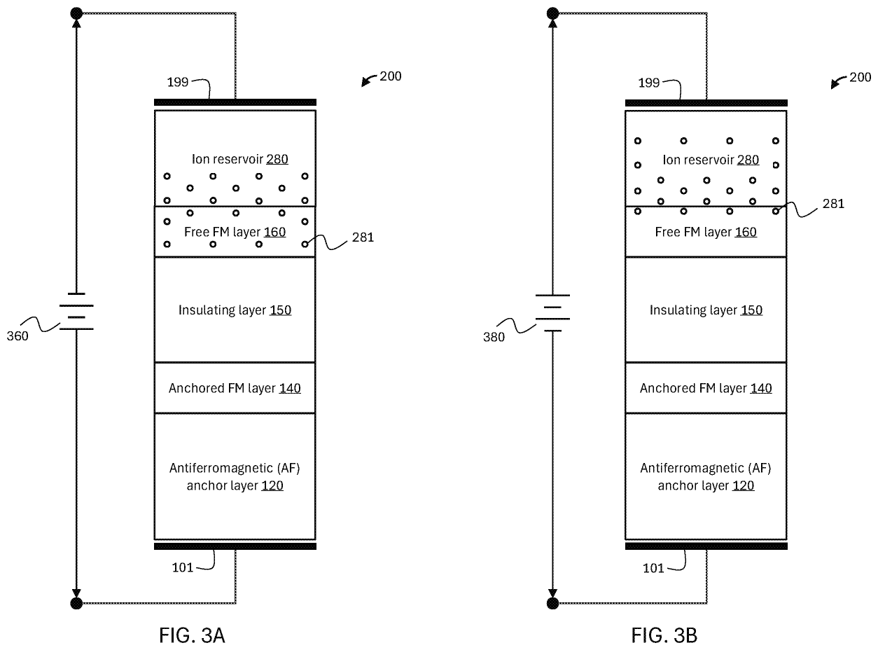

Critically, the magneto-ionic MTJ 200 includes an ion reservoir 280 adjacent to the free FM layer 160 opposite the anchored FM layer 140. The ion reservoir 280 provides a source of ions 281 that, as described in detail below with reference to FIGS. 3A and 3B, can be controllably driven into the free FM layer 160 by application of an electric field.

FIGS. 3A and 3B are block diagrams further illustrating the magneto-ionic MTJ 200 according to exemplary embodiments.

As shown in FIG. 3A, applying a forward bias voltage 360 (e.g., +2 volts) causes ions 281 to migrate from the ion reservoir 280 into the free FM layer 160. Meanwhile, as shown in FIG. 3B, applying a reverse bias voltage 380 (e.g., −2 volts) causes the ions 281 that were driven into the free FM layer 160 from the ion reservoir 280 to migrate back to the ion reservoir 280 from the free FM layer 160.

As demonstrated by the experimental results below, the magneto-ionic MTJ 200 provides a mechanism for electrically controlling the tunnel magnetoresistive state of the magneto-ionic MTJ 200 through the magneto-ionic effect. Driving ions 281 into the free FM layer 160 via application of a forward bias voltage 360 (as shown in FIG. 3A), for example, can be used to reduce the TMR of the magneto-ionic MTJ 200—even below measurable levels. Meanwhile, application of a reverse bias voltage 380 (as shown in FIG. 3B) causes the magneto-ionic MTJ 200 regain some of the TMR.

In the embodiments of FIGS. 2 and 3A-3B, the ion reservoir 280 is adjacent to—and the ions 281 are driven into—the free FM layer 160. In other embodiments, the ion reservoir 280 may be formed adjacent to the anchored FM layer 140. In those embodiments, the ions 281 provided by the ion reservoir 280 may be driven into and from the anchored FM layer 140 in a similar process and with similar effects as described above.

Because the TMR state of the disclosed MTJ 200 can be set via an electric field, the disclosed MTJ 200 can be used to form a binary memory device (e.g., magnetic random access memory or MRAM) that requires significantly less power than devices formed by prior art MTJs. If incorporated into a binary memory device, for example, the disclosed MTJ 200 can be set to a first binary value (e.g., 1) via application of a forward bias voltage 360 and set to the second binary value (0, in this example) via application of a reverse bias voltage 380. The application of that electric field requires significantly less power than prior art MTJs, which require high current densities to switch a bit (resulting in considerable energy dissipation) as described above.

In addition to binary memory devices (e.g., toggling between a maximum TMR state and a minimum TMR state), the configurability of the magneto-ionic MTJ 200 makes it highly adaptable for analog and non-Boolean applications. Because the migration of ions 281 from the ion reservoir 280 is driven by an applied electric field, the depth and concentration of the ion migration—and the resulting change in the magnetic state of the free FM layer 160—can be finely controlled by controlling the bias voltage 360 or 380, varying the duration of the voltage pulses, or applying a sequence of specific voltage waveforms. Because the magneto-ionic MTJ 200 can achieve a continuous range of stable, intermediate TMR states (in addition to a simple binary 0 or 1), the magneto-ionic MTJ 200 can be incorporated into a number of analog and non-Boolean embodiments.

In some embodiments, the magneto-ionic MTJ 200 may be configured to operate as an artificial synapse within a neuromorphic computing architecture. In biological neural networks, synaptic weights vary continuously to facilitate learning and memory. Calibrated electric fields can be applied to the magneto-ionic MTJ 200 to modulate the concentration or depth of the ions 281 in the free FM layer 160 and incrementally adjust the magnetic state, thereby producing a scalable, non-volatile change in the measured TMR. Consequently, the magneto-ionic MTJ 200 can reliably store and update continuous “weight” values in hardware, providing a highly energy-efficient, low-power component for artificial neural networks and machine learning processors.

In other embodiments, the magneto-ionic MTJ 200 may enable multi-bit storage in a high-density memory device. In those embodiments, the continuous tunability of the magneto-ionic MTJ 200 TMR response enables multi-bit storage within a single physical memory cell. By calibrating the electric-field-controlled ionic motion, the magneto-ionic MTJ 200 can be reliably driven into one of three, four, or more distinct, non-volatile resistance states. For instance, a single magneto-ionic MTJ cell 200 can act as a 2-bit storage element representing logical states “00”, “01”, “10”, and “11” by mapping each logical state to a specific, measurable TMR percentage. That multi-bit configuration dramatically increases the data density of a conventional MTJ memory array.

In other embodiments, the tunable nature of the magneto-ionic MTJ 200 may be utilized to provide a dynamic magnetic sensor. While MTJs are widely recognized for their utility in sensor applications, conventional MTJ sensors typically have fixed sensitivity ranges dictated during manufacturing. Incorporated into an MTJ sensor, the magneto-ionic MTJ 200 enables the sensitivity and dynamic range of the sensor to be dynamically adjust via application of distinct bias voltages. For example, a first bias voltage may configure the magneto-ionic MTJ 200 for high-sensitivity detection of minute external magnetic fields, while a second bias voltage may configure the magneto-ionic MTJ 200 to resist saturation when measuring strong magnetic environments.

In other embodiments, arrays of magneto-ionic MTJs 200 may be implemented as physical unclonable functions (PUFs) for hardware security and cryptographic key generation. Due to microscopic, unavoidable manufacturing variations in the ion reservoir 280, the exact migration rate and distribution of the ions 281 will vary slightly from cell to cell. When an identical, intermediate electric field is applied globally across an array of those magneto-ionic MTJs 200, each individual cell will settle into a uniquely distinct analog TMR state based on its localized physical variations. Accordingly, the array of unique TMR states may be used to generate a highly secure, non-volatile, and unclonable hardware fingerprint that can be used to generate unique cryptographic keys or read out to authenticate a device.

### Experimental Results

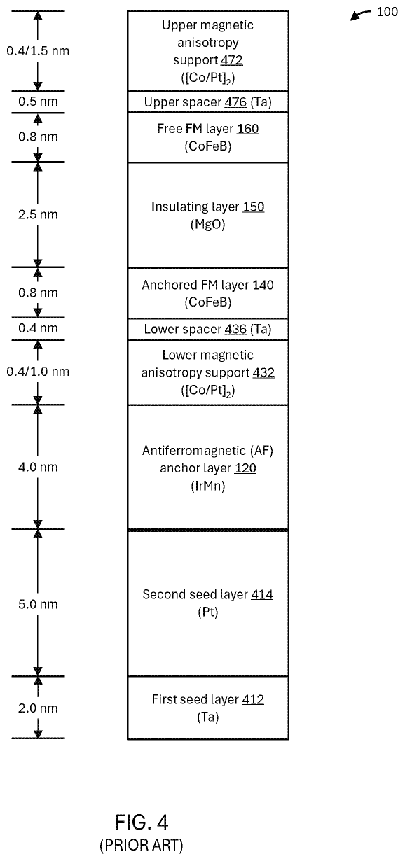

FIG. 4 is a block diagram illustrating a specific example of the prior art MTJ 100 of FIG. 1 in more detail.

As described above with reference to FIGS. 1A and 1B, the prior art MTJ 100 includes an AF anchor layer 120, an anchored FM layer 140, an insulating layer 150, and a free FM layer 160. Additionally, as shown in FIG. 4, the prior art MTJ 100 includes a first seed layer 412, a second seed layer 414, a lower magnetic anisotropy support multilayer 432, a lower spacer 436, an upper spacer 476, and an upper magnetic anisotropy support multilayer 472. In the embodiment of FIG. 4, the first seed layer 412 is a 2.0 nanometer (nm) tantalum (Ta) layer, the second seed layer 414 is a 5.0 nm platinum (Pt) layer, the AF anchor layer 120 is a 4.0 nm iridium manganese (IrMn) layer, the lower magnetic anisotropy support multilayer 432 is two alternating layers of cobalt (Co) and platinum (0.4/1.0 nm ([Co/Pt]₂), the lower spacer 146 is a 0.4 nm Ta layer, the anchored FM layer 140 is a 0.8 nm cobalt iron boron (CoFeB) layer, the insulating layer 150 is a 2.5 nm magnesium oxide (MgO) layer, the free FM layer 160 is a 0.8 nm CoFeB layer, the upper spacer 476 is a 0.5 nm Ta layer, and the upper magnetic anisotropy support multilayer 472 is a 0.4/1.5 nm [Co/Pt]₂ layer.

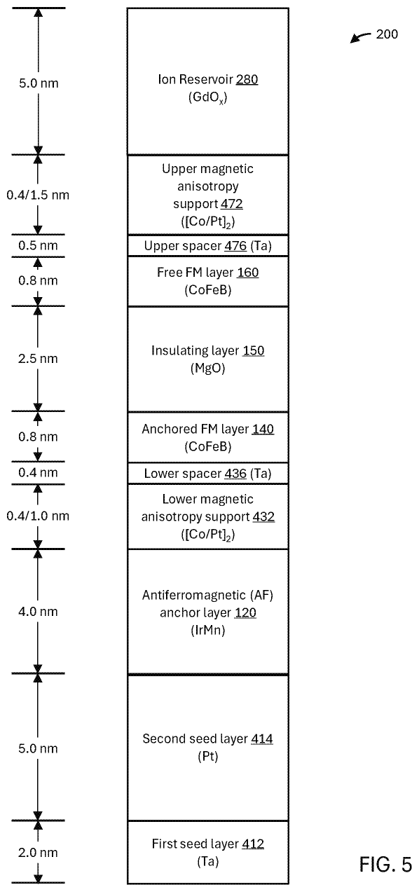

FIG. 5 is a block diagram illustrating a specific exemplary embodiment of the magneto-ionic MTJ 200 of FIGS. 2 and 3A-3B.

In the embodiment of FIG. 5, the magneto-ionic MTJ 200 includes the same structure as the prior art MTJ 100 of FIG. 4 and an ion reservoir 280. In the example of FIG. 5, the ion reservoir 280 is a 5.0 nm gadolinium oxide (GdOₓ) layer.

In the embodiments of FIGS. 4 and 5, the FM layers 140 and 160 have magnetization directions 148 and 168 that are perpendicular to the plane of the respective FM layer 140 or 160 as described above with reference to FIGS. 1A and 1B. In other embodiments, however, the magnetization direction 148 and/or 168 may be “in-plane” (i.e., parallel to the plane formed by the respective layer 140 and/or 160).

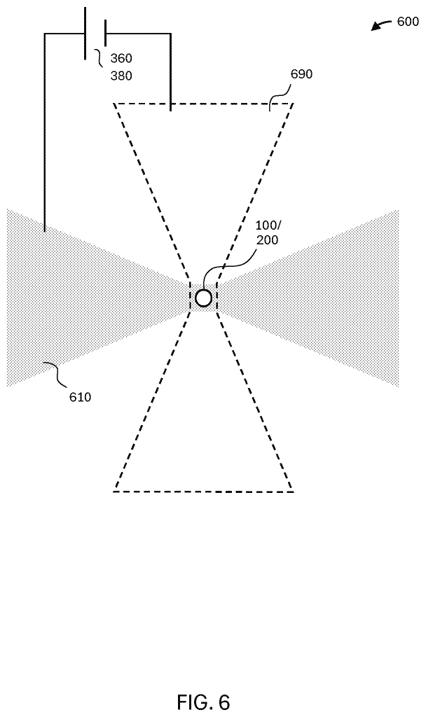

FIG. 6 illustrates a top-down view of a contact pad layout 600 having a bottom electrode 610 electrically connected to the bottom contact 101 of the MTJ device 100 or 200, a top electrode 690 electrically connected to the top contact 199 of the MTJ device 100 or 200, and a voltage source for providing the forward bias voltage 360 (as shown in FIG. 6) and/or the reverse bias voltage 380 (by reversing the voltage polarity shown in FIG. 6).

As shown in FIGS. 4 and 5, two MTJ devices 100 and 200 having a CoFeB/MgO/CoFeB sandwich were fabricated, one MTJ device 200 with a GdOₓ ion reservoir 280 as shown in FIG. 5 (referred to from now on as the GdOₓ MTJ 200) and one MTJ device 100 without a GdOₓ ion reservoir as shown in FIG. 4 (referred to from now on as the reference MTJ 100). Both of the MTJ devices 100 and 200 exhibit perpendicular magnetic anisotropy (PMA), with TMR dependent on the perpendicular alignment between the two FM layers 140 and 160.

Here we report our findings on the switching of TMR through electric field controlled migration of the oxygen ions 281 from the GdOₓ ion reservoir 280. For the reference MTJ device 100, the TMR change was measured to be 9.4% at room temperature. In the GdOₓ MTJ device 200, a significant increase in resistance was observed in the as-grown state at 50 K and the TMR based on the total resistance was measured to be 3.3%. By applying a +2 V forward bias voltage 360 across the MTJ device 200 (e.g., as shown in FIG. 3A and FIG. 6), the TMR of the MTJ device 200 was reduced beyond measurable levels. By reversing the bias direction and applying a −2 V reverse bias voltage 380 across the MTJ device 200 (as shown in FIG. 3B), a TMR of 0.6% was again observed in the MTJ device 200. This toggling of TMR is likely caused by the magnetization direction 168 of the free FM layer 160 rotating in-plane (i.e., substantially orthogonal to the magnetization direction 148 of the anchored FM layer 140) as oxygen ions 281 move to the interface and TMR vanishing as a result. Additionally, the TMR reduction may have contributions from the free FM layer 160 being partially oxidized or changes within the GdOₓ ion reservoir layer 280.

The MTJ devices 100 and 200 of FIGS. 4 and 5 were grown by sputter deposition in several growth and patterning steps by researchers at King Abdullah University of Science and Technology (KAUST) and Georgetown University. All layers up to the GdOₓ ion reservoir layer 280 were grown on a single large SiO₂/Si substrate at KAUST, which was cleaved into two sections. One of these sections had 5 nm of GdOₓ reactively sputtered on top of the free FM layer 160 and was capped with Ta at Georgetown University. The GdOₓ ion reservoir layer 280 was grown in an Ar:O₂ working gas mixture with a flow ratio of 50 sccm:1.4 sccm at 0.67 Pa. The GdOₓ deposited film was returned to KAUST, where final patterning steps were completed on both of the films (with and without GdOₓ) to produce cylindrical MTJs 100 and 200 with a 50 μm diameter. Gold contacts were then deposited onto these cylindrical cores, making two separate connections corresponding to the top contact 199 and the bottom contact 101.

The process outlined above resulted in two full MTJ stacks: the reference MTJ 100 (illustrated in FIG. 4) and the GdOₓ MTJ 200 (illustrated in FIG. 5). These stacks incorporate an IrMn AF layer 120 and [Co/Pt] multilayers 432 and 472 to add additional magnetic anisotropy, particularly to the CoFeB anchored FM layer 140 where the IrMn AF layer 120 resulted in differences in magnetic reversal between the two FM layers 140 and 160. The stacks were annealed at 523 K for 1 hour, with a 50 K/min ramp rate for both increasing and decreasing temperatures, used to increase the TMR observed in the samples. The contacts were wire bonded to a transport probe, allowing a magnetic field normal to the sample surface to be applied.

The electric transport capabilities of the Quantum Design MPMS3 were utilized for the measurement of TMR. The contact configuration (illustrated in FIG. 6) was limited to a standard 2-probe measurement due to both the geometry of the sample and the measurement options available at high resistance. After a sample was mounted onto the transport probe and loaded into the system, a voltage of 0.1 V was supplied, with 4 Hz pulses. Current was measured to calculate resistance as the field was swept between 0.5 T and −0.5 T. Averaging was used to reduce noise, ranging from 20-180 seconds depending on the level of noise, proportional to the total resistance of the samples. Only a single room temperature measurement was taken for each reference MTJ 100, since they were not biased for migration of O²⁻ ions 281. For the GdOₓ MTJ 200, high resistance limited the measurements at room temperature, but measurable TMR could be obtained by lowering the temperature to 50 K.

To drive O²⁻ ions 281 in the GdOₓ MTJ 200, they were first brought to room temperature. A +2 V forward bias voltage 360 was applied, with the positive connection of the voltage supply connected to the bottom electrode 610 of the MTJ 200 as shown in FIG. 3A and FIG. 6. The direction of migration of the O²⁻ions 281 caused by this voltage application is expected to be from the GdOₓ toward the free FM layer 160 in the MTJ stack 200 as shown in FIG. 3A. This forward bias voltage 360 was held for 1 hour, with the sample kept inside the MPMS system. The samples were subsequently measured at 50 K using the same parameters as the as-grown state. After bringing the samples to room temperature, a −2 V reverse bias voltage 380 (i.e., having the negative voltage connection on the bottom electrode 610 of the sample) was then applied for 1 hour. The expected direction of the O²⁻ ion 281 migration was expected to be from the MTJ stack 200 toward the GdOₓ ion reservoir 280 as shown in FIG. 3B. Subsequent measurements were again at 50 K using the same parameters.

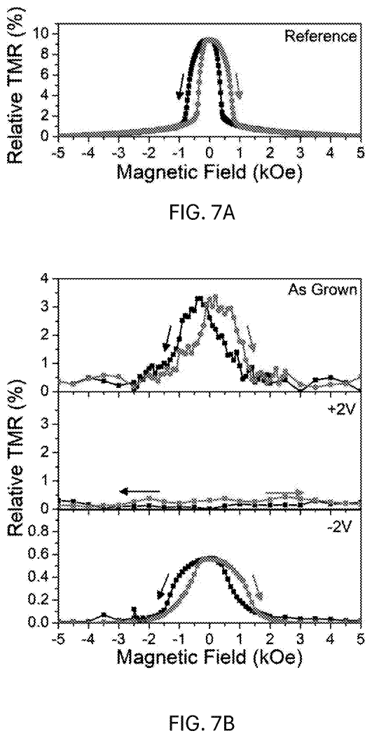

FIG. 7A is a graph illustrating the relative TMR of the reference MTJ 100 as a function of magnetic field. FIG. 7B is a graph illustrating the relative tunnel magnetoresistance, as a function of magnetic field, of the GdOₓ MTJ 200 in its as grown state, after application of a +2 V forward bias voltage 360, and after application of a −2 V reverse bias voltage 380. Here we define the relative TMR as (R_{M}−R_{L})/R_{L}×100%, where R_{L} is the minimum value of resistance, corresponding to parallel alignment between the FM layers 140 and 160 that occurs at sufficiently high magnetic field strengths, and R_{M} is the resistance value measured at each point along the magnetic field sweep. Reported values for TMR are the maximum in the measured relative resistance.

As shown in FIGS. 7A and 7B, the relative resistance for the reference MTJ 100 (FIG. 7A) has significantly less noise compared to the GdOₓ MTJ 200 (FIG. 7B). The higher noise in the GdOₓ MTJ 200 is a result of the additional resistance from the GdOₓ ion reservoir 280, where room temperature resistance measured through the full reference MTJ device 100 had an R_{L} of 30 kΩ and room temperature resistance measured through the full GdOₓ MTJ device 200 had an initial R_{L} of 8 MΩ (which became 60 MΩ at 50K). The TMR for the reference MTJ 100 was 9.4% (a modest value compared to other recent MgO-based MTJs reported in literature that may be further enhanced by optimizing the annealing conditions).

Initially, the TMR measurement temperature was reduced in an effort to overcome the higher noise in the GdOₓ MTJ 200. It was believed that the TMR magnitude (2.8 kΩ for the reference MTJ 100) would be the same based on the assumption that the only contributions to the TMR would be from the identical CoFeB/MgO/CoFeB layers. Interestingly, as temperature was reduced, there was a significant increase in overall resistance that stabilized at about 60 MΩ at 50 K. This increase is attributed to changes in the GdOₓ layer 280, as the reference MTJ 100 had only a slight increase in total resistance to 36 kΩ. It should be noted that the broader shape in the TMR response for the GdOₓ MTJ 200 compared to the reference MTJ 100 is caused by an increase in coercivity in the FM layers 140 and 160 as temperature is reduced, and a similar increase is seen in the reference MTJ 100 at 50 K (not shown). Despite almost an order of magnitude increase in resistance, in the as-grown state of the GdOₓ MTJ 200, a TMR of 3.3% was observed (shown in the top panel of FIG. 7B), where the magnitude of change in TMR is 1.6 MΩ. This change cannot be attributed to the CoFeB/MgO/CoFeB layers alone, as the reference sample measured at 50 K had very little change in TMR compared to room temperature.

The effect of driving O²⁻ ions 281 was then explored via voltage application to produce an electric field across the GdOₓ MTJ 200. When they were initially biased at +2 V at room temperature and subsequently measured at 50 K, a reduction of TMR to below the measurement noise level was observed, as seen in the second panel of FIG. 7B. The resistance of the GdOₓ MTJ device 200 decreased to 13 MΩ. By reversing the bias direction and applying voltage at room temperature, TMR again becomes observable in the GdOₓ MTJ device 200 when measured at 50 K, shown in the last panel of FIG. 7B. The TMR corresponding to the reversed biased state is 0.6% at 50 K. This reversed biased state also has a significant reduction in overall resistance (R_{L}=308 kΩ). Considering this, the 0.6% TMR corresponds to a resistance change 1.8 kΩ, which is now on the order of magnitude of the TMR values at room temperature of the reference MTJ 100.

The experimental results demonstrate an important practical device platform for magneto-ionics in an MTJ structure 200. Upon biasing, with a voltage direction corresponding to motion of O²⁻ ions 281 toward the free FM interface 160 from the GdOₓ ion reservoir 280, the TMR could be reduced from 3.3% in the as-grown state to a negligible value. Upon reverse biasing, TMR of 0.6% was again observed, with the same position and coercivity as the as-grown state. These findings can be explained by several potential effects of O²⁻ ion 281 migration, or a combination of them, including PMA changes as O²⁻ ions 281 move toward the free FM layer 160, oxidation of the free FM layer 160, or changes within GdOₓ ion reservoir 280 itself. Accordingly, the experimental results serve as a prototype device demonstration of magneto-ionics for magnetic memory and logic, with the possibility to reduce energy consumption and improve scaling in devices such as MRAM. This new handle on the electric control of magnetism may also go beyond the two-state manipulation of current magnetic memory devices towards tuning the magnetic state in an analog manner. This enables magneto-ionics to be used as synaptic devices and become an important component of next-generation spintronic based neuromorphic devices.

While preferred embodiments have been described above, those skilled in the art who have reviewed the present disclosure will readily appreciate that other embodiments can be realized within the scope of the invention. Accordingly, the present invention should be construed as limited only by any appended claims.

What is claimed is:

1. A magneto-ionic magnetic tunnel junction (MTJ) device, comprising:
an MTJ, comprising:
two ferromagnetic (FM) layers;
an insulating layer separating the two ferromagnetic (FM) layers; and
an antiferromagnetic (AF) anchor layer that anchors a magnetization direction of one of the FM layers;
an ion reservoir adjacent to one of the FM layers; and
a voltage source configured to drive ions from the ion reservoir to the adjacent FM layer by applying a bias voltage across the MTJ.

2. The magneto-ionic MTJ device of claim 1, wherein:
the voltage source is configured to drive the ions from the ion reservoir to the adjacent FM layer by applying a forward bias voltage across the MTJ; and
the voltage source is further configured to drive at least some of the driven ions to the ion reservoir by applying a reverse bias voltage across the MTJ.

3. The magneto-ionic MTJ device of claim 1, wherein the voltage source is configured to reduce the tunnel magnetoresistance (TMR) of the MTJ by applying a forward bias voltage across the MTJ.

4. The magneto-ionic MTJ device of claim 3, wherein the voltage source is configured to substantially eliminate the TMR of the MTJ by applying the forward bias voltage across the MTJ.

5. The magneto-ionic MTJ device of claim 3, wherein the voltage source is further configured to increase the TMR of the MTJ by applying a reverse bias voltage across the MTJ.

6. The magneto-ionic MTJ device of claim 1, wherein the MTJ is incorporated in a binary memory device and configured to store a binary value.

7. The magneto-ionic MTJ device of claim 6, wherein:
the voltage source sets a first binary value stored in the MTJ by applying a forward bias voltage; and
the voltage source sets a second binary value stored in the MTJ by applying a reverse bias voltage.

8. The magneto-ionic MTJ device of claim 1, wherein:
the MTJ forms an artificial synapse within a neuromorphic computing architecture; and
the voltage source is configured to specify a weight of the artificial synapse by applying calibrated electric fields across the MTJ.

9. The magneto-ionic MTJ device of claim 1, wherein:
the MTJ forms a multi-bit storage element for storing a multi-bit value; and
the voltage source is configured to specify the multi-bit value stored by selectively applying bias voltages across the MTJ.

10. The magneto-ionic MTJ device of claim 1, wherein:
the MTJ is incorporated into a magnetic sensor having a sensitivity and a dynamic range; and
the voltage source is configured to dynamically adjust the sensitivity or the dynamic range by selectively applying bias voltages across the MTJ.

11. A method of making a magneto-ionic magnetic tunnel junction (MTJ) device, the method comprising:
forming an MTJ, comprising:
two ferromagnetic (FM) layers;
an insulating layer separating the two FM layers; and
an antiferromagnetic (AF) anchor layer that anchors a magnetization direction of one of the FM layers;
depositing an ion reservoir adjacent to one of the FM layers; and
applying a bias voltage across the MTJ to drive ions from the ion reservoir to the adjacent FM layer.

12. The method of claim 11, wherein applying the bias voltage across the MTJ to drive ions from the ion reservoir to the adjacent FM layer comprises applying a forward bias voltage across the MTJ, the method further comprising:
driving at least some of the driven ions to the ion reservoir by applying a reverse bias voltage across the MTJ.

13. The method of claim 11, wherein driving the ions from the ion reservoir to the adjacent FM layer reduces the tunnel magnetoresistance (TMR) of the MTJ.

14. The method of claim 13, further comprising:
increasing the TMR of the MTJ by applying a reverse bias voltage across the MTJ.

15. The method of claim 11, wherein driving the ions from the ion reservoir to the adjacent FM layer substantially eliminates the TMR of the MTJ.

16. The method of claim 11, wherein the MTJ is incorporated in a binary memory device, the method further comprising:
storing a binary value in the MTJ by selectively applying a bias voltage across the MTJ.

17. The method of claim 16, wherein selectively applying a bias voltage comprises:
storing a first binary value in the MTJ by applying a forward bias voltage; and
storing a second binary value stored in the MTJ by applying a reverse bias voltage.

18. The method of claim 11, wherein the MTJ forms an artificial synapse within a neuromorphic computing architecture, the method further comprising:
specifying a weight of the artificial synapse by selectively applying calibrated electric fields across the MTJ.

19. The method of claim 11, wherein the MTJ forms a multi-bit storage element, the method further comprising:
storing a multi-bit value in the MTJ by selectively applying bias voltages across the MTJ.

20. The method of claim 11, wherein the MTJ is incorporated into a magnetic sensor having a sensitivity and a dynamic range, the method comprising:
dynamically adjusting the sensitivity or the dynamic range by selectively applying bias voltages across the MTJ.
